(19) United States
(12) Patent Application Publication
(10) Pub. No.: US 2013/0221487 A1
(43) Pub. Date: Aug. 29, 2013

(54) METHOD OF FORMING RESISTOR OF SEMICONDUCTOR MEMORY DEVICE AND STRUCTURE THEREOF

(71) Applicant: Jeong Guen PARK, Icheon-si (KR)

(72) Inventor: Jeong Guen PARK, Icheon-si (KR)

(73) Assignee: SK hynix Inc., Icheon-si (KR)

(21) Appl. No.: 13/604,468

(22) Filed: Sep. 5, 2012

(30) Foreign Application Priority Data
Feb. 24, 2012 (KR) 10-2012-0018911

(51) Int. Cl. H01L 29/86; H01L 21/02

(52) U.S. Cl. 257/536; 438/382; 257/E21.004; 257/E29.325

(57) ABSTRACT

A resistor in a semiconductor memory device is formed by the steps of, inter alia: forming a first helical resistor extending from a first point toward a center in a clockwise or counterclockwise direction, forming a second helical resistor extending from the center to a second point in an opposite direction, wherein the first and second helical resistors are connected to each other at the center, and wherein the first and second helical resistors do not overlap.

### CROSS-REFERENCES TO RELATED APPLICATION

The present application claims priority under 35 U.S.C. §119(a) to Korean application number 10-2012-0018911, filed on Feb. 24, 2012, in the Korean Intellectual Property Office, which is incorporated herein by reference in its entirety.

### BACKGROUND

1. Technical Field

The present invention relates generally to a method of fabricating a semiconductor memory device and a structure thereof, and more particularly, to a method of forming a resistor of a semiconductor memory device and a structure thereof.

2. Related Art

In general, the semiconductor memory devices for data storage may be classified as either volatile or nonvolatile memory devices.

The volatile memory device represented by DRAM or SRAM performs a data input/output operation at high speed, but loses data stored therein when the power supply is cut off. Furthermore, the nonvolatile memory device represented by a NAND or NOR flash memory based on EEROM (Electrically Erasable Programmable Read Only Memory) maintains data stored therein even though the power supply is cut off.

Therefore, with the fast paced development of the information communication technology and the wide spread use of information media such as computers, the demand for next-generation memory devices operating at an ultra high speed in terms of functions and having a large memory storage capacities have gradually increased.

The next-generation memory devices have been developed by combining the advantages of the volatile memory device such as DRAM and the nonvolatile memory device such as Flash memory, and exhibit excellent data retention and read/write characteristics while having small power consumption during operation. The next-generation memory devices may include FRAM (Ferroelectric Random Access Memory), MRAM (Magnetic Random Access Memory), PRAM (Phase-change Random Access Memory) or NFGM (Nano Floating Gate Memory).

Each of the above-described various types of semiconductor memory devices are typically divided into a cell area and a peripheral circuit area. The cell area is where a plurality of word lines and bit lines and a plurality of memory cells are formed. The peripheral circuit area is where elements for driving/controlling the memory cells formed in the cell area, for example, transistors and diodes serving as active elements and capacitors and resistors serving as passive elements are formed.

In particular, a resistor plays a very important role for the operation of an electronic circuit, and may be fabricated in various sizes depending on the use of a semiconductor memory device. The resistor is generally formed of a conductive material having specific resistance, integrated into a semiconductor memory device, and used for delaying a signal, adjusting a timing, or acquiring a desired voltage level, among others.

FIG. 1 illustrates a conventional zigzag-shaped resistor 10.

Referring to FIG. 1, the resistor 10 has a structure in which a zigzag-shaped path extends from an in-terminal 12 to an out-terminal 14. As the area of the resistor is increased to raise a resistance value, the distance between the in-terminal 12 and the out-terminal 14 increases.

The resistor 10 is implemented in a peripheral circuit area and serves as a passive element for driving/controlling memory cells formed in a cell area. When the distance between the in-terminal 12 and the out-terminal 14 becomes more distant from each other, the lengths of interconnection lines 18 and 20 for electrically connecting a logic circuit of the cell area to the in-terminal 12 and the out-terminal 14 also differ from each other. Since the out-terminal 14 is positioned at a farther distance corresponding to a straight-line distance of the resistor area from the in-terminal 12 to the out-terminal 14 as indicated by ‘A’, the length of the interconnection line for connection with the logic circuit is increased by the straight-line distance ‘A’.

When the length of the interconnection line for connecting the logic circuit to the out-terminal 14 is increased, an electrical error may occur in the semiconductor memory device because of various factors which incidentally occur in addition to the resistor which is previously formed. Such a problem will be described in more detail with reference to FIG. 2.

FIG. 2 illustrates an example in which the resistor 10 illustrated in FIG. 1 is connected to a logic circuit 16.

Referring to FIG. 2, the resistor 10 serving as a passive element is implemented next to the logic circuit 16 of the semiconductor memory cell area. The resistor 10 is formed in a zigzag shape, and spaced at a predetermined distance from the logic circuit 16. Furthermore, the in-terminal 12 and the out-terminal 14 of the resistor 10 are electrically connected to the logic circuit 16 through interconnection lines 18 and 20, respectively.

The resistor 10 has a structure in which the length of the in-terminal interconnection line 18 for connecting the logic circuit 16 to the in-terminal 12 is different from the length of the out-terminal interconnection line 20 for connecting the logic circuit 16 to the out-terminal 14. As illustrated in FIG. 2, the length of the interconnection line 20 for connecting the logic circuit 16 to the out-terminal 14 becomes larger by the straight-line distance factor ‘A’ than the length of the interconnection line 18 for connecting the logic circuit 16 to the in-terminal 12. The length difference between the interconnection lines further increases as the physical size of the resistor is increased.

The resistor 10 has a structure in which the in-terminal 12 is positioned adjacent to the logic circuit. Therefore, the length of the interconnection line 18 of the in-terminal 12 does not have a large effect upon a specific resistance value. However, since the out-terminal 14 is positioned at a farther distance from the logic circuit 16, the length of the interconnection line 20 of the out-terminal 14 is larger than that of the interconnection line 18 of the in-terminal 12. Thus, an R/C value of the interconnection line 20 is added to the specific resistance value of the resistor 10, which may be confirmed via comparison of a line-modeled simulation result and an actual measurement value on the layout.

Such an error further increases as the size of the resistor is increased to acquire a large resistance value. This is because the out-terminal becomes farther distant from the logic circuit. Accordingly, the electrical characteristic of the semiconductor memory device is degraded to significantly reduce the reliability, thereby causing a yield reduction.

### SUMMARY

In an embodiment of the present invention, a method for forming a resistor of a semiconductor memory device includes the steps of: forming a first helical resistor connected from an edge toward a center, forming a second helical resistor connected from the center, where the first helical resistor ends, to another edge, and connecting the second helical resistor to the first helical resistor.

In a variation of an embodiment of the present invention, a method for forming a resistor of a semiconductor memory device includes the steps of: forming a first helical resistor connected from an edge toward a center, forming a second helical resistor connected from the center, where the first helical resistor ends, to another edge, and forming a contact at the center where the first and second helical resistors meet each other such that the contact electrically connects the first and second helical resistors.

In another variation of an embodiment of the present invention, a method for forming a resistor of a semiconductor memory device includes the steps of: forming a first helical resistor connected from an edge toward a center, forming a second helical resistor connected from the center, where the first helical resistor ends, to another edge, connecting the second helical resistor to the first helical resistor, maintaining a predetermined distance from each other so as not to overlap each other, and forming a dummy pattern between the first and second helical resistors.

In yet another variation of an embodiment of the present invention, a method for forming a resistor of a semiconductor memory device includes the steps of: forming a first resistor helically-connected from an edge toward a center, forming a second resistor having the same shape on a different planar dimension as the first resistor, the second resistor helically-connected from the center, where the first helical resistor ends, to another edge, and forming a contact at the center to electrically connect the first and second resistors formed at different layers.

In another embodiment of the present invention, a method for forming a resistor of a semiconductor memory device includes the steps of: forming a first resistor including a first helical resistor connected from an edge to a center and a second helical resistor connected from the center, where the first helical resistor ends, to another edge, and forming a second resistor having the same shape on a different planar dimension as the first resistor, the second resistor including a first helical resistor connected from an edge to a center and a second helical resistor connected from the center, where the first helical resistor ends, to another edge.

In another embodiment of the present invention, a resistor structure of a semiconductor memory device includes: a first helical resistor connected from an edge to a center, a second helical resistor connected from the center, where the first helical resistor ends, to another edge, and connected to the first helical resistor.

In a variation of an embodiment of the present invention, a resistor structure of a semiconductor memory device includes: a first helical resistor connected from an edge to a center, a second helical resistor connected from the center, where the first helical resistor ends, to another edge, and a contact formed at the center to electrically connect the first and second resistors.

In another variation of an embodiment of the present invention, a resistor structure of a semiconductor memory device includes: a first helical resistor connected from an edge to a center, a second helical resistor connected from the center, where the first helical resistor ends, to another edge, maintaining a predetermined distance from each other so as not to overlap each other, and a dummy pattern formed between the first and second resistors.

In yet another variation of an embodiment of the present invention, a resistor structure of a semiconductor memory device includes: a first resistor helically-connected from an edge to a center, a second resistor formed in the same shape on a different planar dimension as the first helical resistor, and helically-connected from the center, where the first helical resistor ends, to another edge, and a contact formed at the center to electrically connect the first and second resistors formed at different layers.

In another embodiment of the present invention, a resistor structure of a semiconductor memory device includes: a first resistor including a first helical resistor connected from an edge to a center and a second helical resistor connected from the center, where the first helical resistor ends, to another edge, and a second resistor formed in the same shape on a different planar dimension as the first resistor, the second resistor including a first helical resistor connected from an edge to a center and a second helical resistor connected from the center, where the first helical resistor ends, to another edge.

### BRIEF DESCRIPTION OF THE DRAWINGS

Features, aspects, and embodiments are described in conjunction with the attached drawings, in which:

FIG. 1 illustrates a conventional resistor structure;

FIG. 2 illustrates an example of a conventional resistor connected to a logic circuit;

FIG. 3 illustrates a resistor structure according an embodiment of the present invention;

FIG. 4 illustrates a variation of a resistor structure according to an embodiment of the present invention shown in FIG. 3;

FIG. 5 illustrates another variation of resistor structure according to an embodiment of the present invention;

FIG. 6 illustrates yet another variation of a resistor structure according to an embodiment of the present invention shown in FIG. 3;

FIG. 7 illustrates a resistor structure according to another embodiment of the present invention; and

FIG. 8 illustrates a variation of a resistor structure according to an embodiment of the present invention shown in FIG. 7.

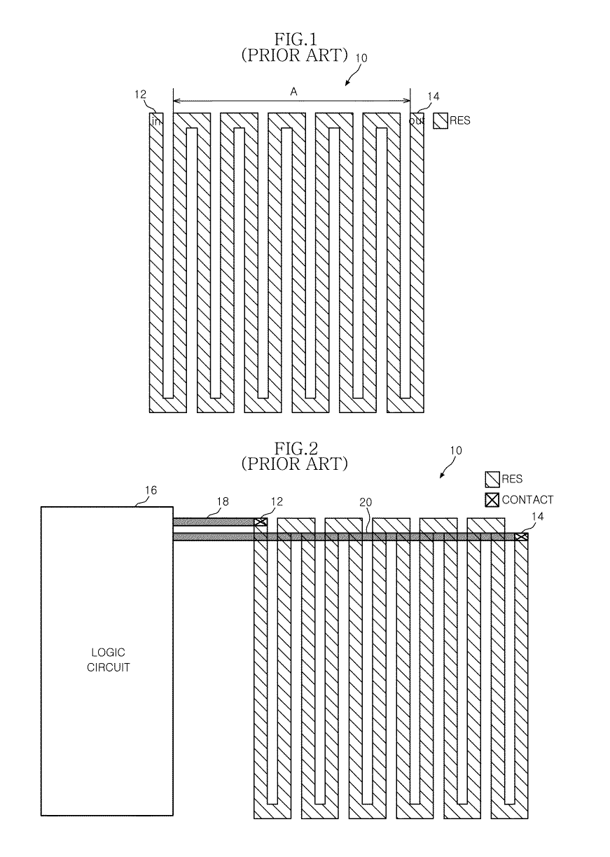

### DETAILED DESCRIPTION

Hereinafter, a method of fabricating a resistor of a semiconductor memory device and a structure thereof according to the present invention will be described below with reference to the accompanying drawings through various embodiments.

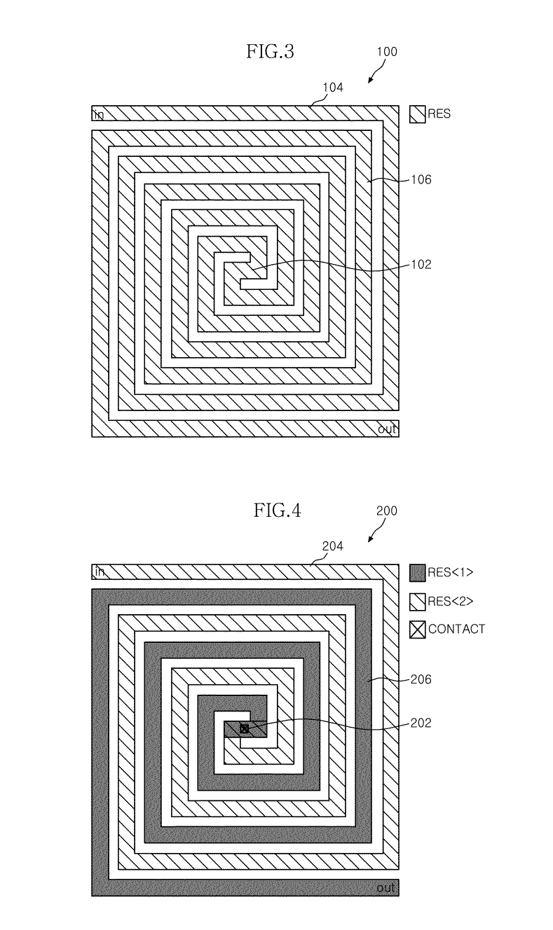

FIG. 3 illustrates a resistor 100 having a double-helical structure according to an embodiment of the present invention.

Referring to FIG. 3, the resistor 100 includes one in-terminal and one out-terminal, and has a double-helical structure. More specifically, the resistor 100 includes a first helical resistor 104 connected from an edge thereof toward a center 102, and a second helical resistor 106 connected from the center 102 toward another edge thereof.

The first helical resistor 104 ends at the center 102, and the second helical resistor 106 starts from the center 102. The center 102 is where the first helical resistor 104 ends and where the second helical resistor 106 starts, and may serve as a turning point for implementing the shape of the resistor 100 in which the first helical resistor is connected from the edge to the center and the second helical resistor is connected from the center to the edge.

The first and second helical resistors 104 and 106 are formed of the same material, and formed at the same layer. Therefore, a contact for electrically connecting the two resistors 104 and 106 is not necessarily formed.

When the resistor 100 is formed in such a double-helical structure as an embodiment of the present invention, the position of the out-terminal as well as the in-terminal may be freely selected. Thus, as the difference in distance between the logic circuit and the in- and out-terminals is minimized, it is possible to minimize the effect of an R/C value of the interconnection line of the out-terminal in addition to a specific resistance value. In the conventional zigzag-shaped resistor as shown in FIG. 2, the out-terminal 14 is withdrawn at the straight-line distance of the resistor area formed in a zigzag shape from the in-terminal 12. As the distance between the logic circuit and the out-terminal is increased, the R/C value of the interconnection line of the out-terminal is inevitably added to the entire resistance value. In the above-described resistor 100 having a double-helical structure, the position of the out-terminal may be freely adjusted to minimize the distance between the out-terminal and the logic circuit. Thus, the effect of the R/C value of the interconnection line may be minimized to thereby improve the reliability of the semiconductor memory device.

FIG. 4 illustrates a resistor 200 having a double-helical structure according to a variation of an embodiment of the present invention.

Referring to FIG. 4, the resistor 200 includes one in-terminal and one out-terminal, and has a double-helical structure. The resistor 200 includes a first helical resistor 204 connected from an edge thereof to a center 202 and a second helical resistor 206 connected from the center 202 to another edge thereof.

The first and second helical resistors 204 and 206 are formed of different materials. Thus, a contact for electrically connecting the two resistors is formed at the center 202 where the two resistors 204 and 206 meet each other.

The first helical resistor 204 ends at the center 202, and the second helical resistor 206 starts from the center 202. Therefore, the center 202 may serve as a turning point where the first helical resistor 204 ends and the second helical resistor 206 starts.

When the resistor 200 is formed in such a double-helical structure as in the variation of an embodiment of the present invention, the position of the out-terminal as well as the in-terminal may be freely selected. Thus, as the difference in distance between the logic circuit and the in- and out-terminals is minimized, it is possible to minimize the effect of an R/C value of the interconnection line of the out-terminal in addition to a specific resistance value. As the distance between the logic circuit and the out-terminal is increased, the R/C value of the interconnection line of the out-terminal is inevitably added to the entire resistance value. In the above-described resistor 200 having a double-helical structure, the position of the out-terminal may be freely adjusted to minimize the distance between the out-terminal and the logic circuit. Thus, the effect of the R/C value of the interconnection line may be minimized to thereby improve the reliability of the semiconductor memory device.

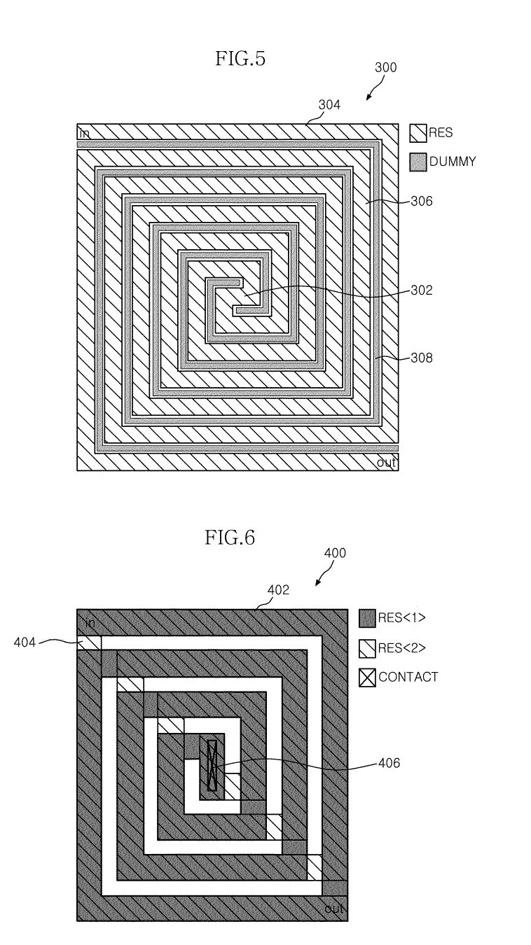

FIG. 5 illustrates a resistor 300 having a double-helical structure according to another variation of an embodiment of the present invention.

Referring to FIG. 5, the resistor 300 includes one in-terminal and one out-terminal, and has a double-helical structure. The resistor 300 includes a first helical resistor 304 connected from an edge thereof to a center 302 and a second helical resistor 306 connected from the center 302 to another edge thereof. Additionally, the resistor 300 includes a dummy pattern 308 formed between the first and second helical resistors 304 and 306 to protect the resistor.

The first helical resistor 304 ends at the center 302, and the second helical resistor 306 starts from the center 302. The center 302 may serve as a turning point where the first helical resistor 304 ends and the second helical resistor 306 starts.

The first and second helical resistors 304 and 306 may be formed of the same material or different materials. First, when the first and second helical resistors 304 and 306 are formed of the same material, the resistor 300 has the same shape as the resistor 100 according to an embodiment of the present invention, and thus does not require a contact for electrically connecting the two resistors 304 and 306. However, when the first and second helical resistors 304 and 306 are formed of different materials, the resistor 300 has the same shape as the resistor 200 according to a variation of an embodiment of the present invention, and thus additionally requires a contact for electrically connecting the two resistors 304 and 306.

Additionally, a dummy pattern 306 is formed between the first and second helical resistors 304 and 306. The dummy pattern 308 may be formed of an insulator such as oxide or nitride. When the resistor 300 is compared to the resistors 100 and 200 according to an embodiment of the present invention, the resistor 300 has a similar structure to the resistors 100 and 200, but has an advantage in that the resistor 300 is more positively protected from an external stress by the dummy pattern 308 formed between the first and second helical resistors 304 and 306 than the first and second resistors 100 and 200.

When the resistor 300 is formed in such a double-helical structure as another variation of an embodiment of the present invention, the position of the out-terminal as well as the in-terminal may be freely selected. As a difference in distance between the logic circuit and the in- and out-terminals is minimized, it is possible to minimize the effect of an R/C value of the interconnection line of the out-terminal in addition to a specific resistance value. As the distance between the logic circuit and the out-terminal is increased, the R/C value of the interconnection line of the out-terminal is inevitably added to the entire resistance value. In the above-described resistor 300 having a double-helical structure, the position of the out-terminal may be freely adjusted to minimize the distance between the out-terminal and the logic circuit. Thus, the effect of the R/C value of the interconnection line may be minimized to thereby improve the reliability of the semiconductor memory device.

FIG. 6 illustrates a resistor 400 having a helical structure according to yet another variation of an embodiment of the present invention.

Referring to FIG. 6, the resistor 400 includes one in-terminal and one out-terminal, and has a double-layer structure of a helical bottom resistor 402 and a helical top resistor 404. The bottom resistor 402 is helically connected from an edge to the center of the resistor 400, and the top resistor 404 is helically connected from the center to another edge of the resistor 400.

The bottom and top resistors 402 and 404 may be formed of the same material or different materials. However, since the bottom and top resistors 402 and 404 of the resistor 400 are formed at different layers unlike the resistors 100 to 300 according to an embodiment of the present invention, the bottom and top resistors 402 and 404 are electrically connected to each other through a contact 406 formed in the center of the resistor 400, regardless of whether the bottom and top resistors 402 and 404 are formed of the same material or different materials. Therefore, since the bottom and top resistors 402 and 404 are electrically connected to each other through the contact 406 even through they are formed at different layers, they form one resistor as a whole.

The bottom resistor 402 ends at the center where the contact 406 is formed, and the top resistor 404 starts from the center where the contact 406 is formed. Thus, the contact 406 may serve as a turning point where the bottom resistor 402 ends and the top resistor 404 starts.

When the resistor 400 is formed in such a double-helical structure as in yet another variation of an embodiment of the present invention, the position of the out-terminal as well as the in-terminal may be freely selected. As a difference in distance between the logic circuit and the in- and out-terminals is minimized, it is possible to minimize the effect of an R/C value of the interconnection line of the out-terminal in addition to a specific resistance value. As the distance between the logic circuit and the out-terminal is increased, the R/C value of the interconnection line of the out-terminal is inevitably added to the entire resistance value. In the above-described resistor 400 having a double-helical structure, however, the position of the out-terminal may be freely adjusted to minimize the distance between the out-terminal and the logic circuit. Thus, the effect of the R/C value of the interconnection line may be minimized to thereby improve the reliability of the semiconductor memory device.

In the resistor 400 according to yet another variation of an embodiment of the present invention, the bottom and top resistors 402 and 404 are formed at different layers. However, since the bottom and top resistors 402 and 404 are formed in the same shape on different layers, they look like one resistor when viewed from above. Therefore, the total length of the resistor is almost equal to those of the resistors 100 to 300, but the entire area occupied by the resistor in the peripheral circuit may be reduced to about ½. Therefore, the resistor 400 has an advantage in terms of high integration.

As described above, the resistor 400 according to yet another variation of an embodiment of the present invention has a stacked structure consisting of only the bottom and top resistors 402 and 404. However, the number of resistor layers to be stacked may be changed. Therefore, as the number of resistor layers to be stacked in the same shape is adjusted, the entire resistance value may be freely increased two or more times without additional area occupation.

Dummy patterns may be formed at the bottom and top resistors 402 and 404, respectively. In this case, the bottom and top resistors 402 and 404 may be more positively protected from an external stress by the dummy patterns.

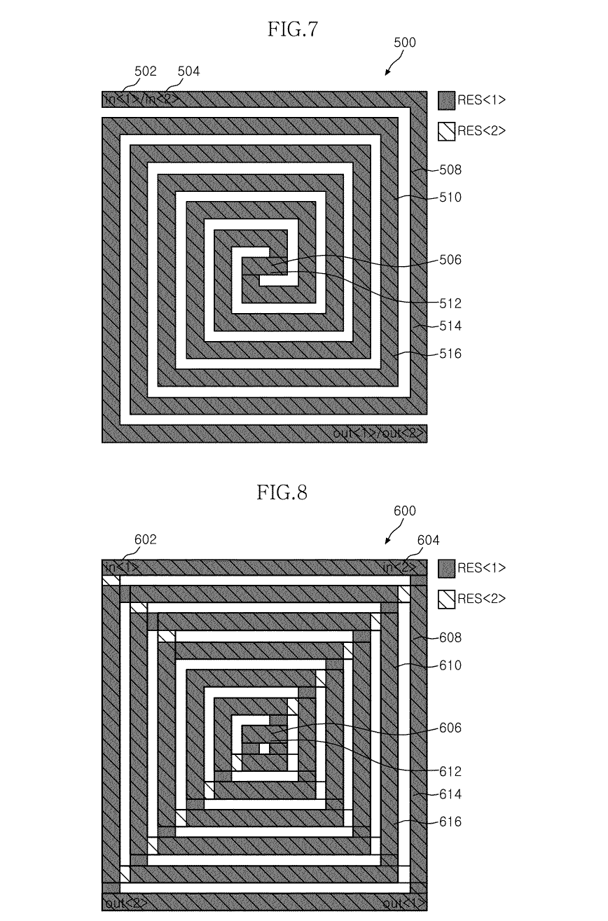

FIG. 7 illustrates a resistor 500 having a double-helical structure according to another embodiment of the present invention.

Referring to FIG. 7, the resistor 500 has a double-layer structure of a bottom resistor 502 and a top resistor 504. The bottom resistor 502 having a double-helical structure includes one in-terminal in<1> and one out-terminal out<1>, and the bottom resistor 504 having a double-helical structure includes one in-terminal in<2> and one out-terminal out<2>. Here, the bottom resistor 502 and the top resistor 504 are independent of each other, and a contact for electrically connecting the two resistor layers 502 and 504 may not be formed.

The bottom resistor 502 includes a first helical resistor 508 connected from an edge thereof to a center 506 and a second helical resistor 510 connected from the center 506 to another edge thereof. The top resistor 504 also includes a first helical resistor 514 connected from an edge thereof to a center 512 and a second helical resistor 516 connected from the center 512 to another edge thereof.

The first helical resistor 508 of the bottom resistor 502 ends at the center 506, and the second helical resistor 510 starts from the center 506. Therefore, the center 506 may serve as a turning point where the first helical resistor 508 ends and the second helical resistor 510 starts.

The first helical resistor 514 of the top resistor 504 also ends at the center 512, and the second helical resistor 516 starts from the center 512. Thus, the center 512 may serve as a turning point where the first helical resistor 514 ends and the second helical resistor 516 starts.

The bottom and top resistors 502 and 504 may be formed of the same material or different materials. The first and second helical resistors 508 and 510 of the bottom resistor 502 may also be formed of the same material or different materials. When the first and second helical resistors 508 and 510 are formed of the same material, the resistor 500 has the same shape as the resistor 100 according to an embodiment of the present invention, and thus may not require a contact for electrically connecting the two resistors 508 and 510. However, when the first and second helical resistors 508 and 510 are formed of different materials, the resistor 500 has the same shape as the resistor 200 according to an embodiment of the present invention, and thus additionally requires a contact for electrically connecting the two resistors 508 and 510.

The first and second helical resistors 514 and 516 of the top resistor 504 may be formed of the same material or different materials. When the first and second helical resistors 514 and 516 are formed of the same material, the resistor 500 has the same shape as the resistor 100 according to an embodiment of the present invention, and thus does not require a contact for electrically connecting the two resistors 514 and 516. However, when the first and second helical resistors 514 and 516 are formed of different materials, the resistor 500 has the same shape as the resistor 200 according to a variation of an embodiment of the present invention, and thus additionally requires a contact for electrically connecting the two resistors 514 and 516.

When the resistor 500 is formed in such a double-helical structure as in another embodiment of the present invention, the position of the out-terminal as well as the in-terminal may be freely selected. As a difference in distance between the logic circuit and the in- and out-terminals is minimized, it is possible to minimize the effect of an R/C value of the interconnection line of the out-terminal in addition to a specific resistance value. As the distance between the logic circuit and the out-terminal is increased, the R/C value of the interconnection line of the out-terminal is inevitably added to the entire resistance value. In the above-described resistor 500 having a double-helical structure, however, the position of the out-terminal may be freely adjusted to minimize the distance between the out-terminal and the logic circuit. Thus, the effect of the R/C value of the interconnection line may be minimized to thereby improve the reliability of the semiconductor memory device.

As described above, the resistor 500 according to another embodiment of the present invention has a stacked structure consisting of only the bottom and top resistors 502 and 504. However, the number of resistor layers to be stacked may be changed. Therefore, as the number of resistor layers to be stacked in the same shape is adjusted, a plurality of independent resistors each having an in-terminal and an out-terminal may be freely formed without additional area occupation.

Dummy patterns may be formed in the bottom and top resistors 502 and 504, respectively. In this case, the bottom and top resistors 502 and 504 may be more positively protected from an external stress by the dummy patterns.

FIG. 8 illustrates a resistor 600 having a double-helical structure according to variation of another embodiment of the present invention.

Referring to FIG. 8, the resistor 600 has a double-layer structure consisting of a bottom resistor 602 and a top resistor 604. The bottom resistor 602 has a double-helical structure with one in-terminal in<1> and one out-terminal out<1>, and the top resistor 604 has a double-helical structure with one in-terminal in<2> and one out-terminal out<2>. The bottom and top resistors 602 and 604 are independent of each other, and a contact for electrically connecting the two resistor layers 602 and 604 may not formed.

The bottom resistor 602 includes a first helical resistor 608 connected from an edge thereof to a center 606 and a second helical resistor 610 connected from the center 606 to another edge thereof. The top resistor 604 includes a first helical resistor 614 connected from an edge thereof to a center 612 and a second helical resistor 616 connected from the center 612 to another edge thereof.

The first helical resistor 608 of the bottom resistor 602 ends at the center 606, and the second helical resistor 610 starts from the center 606. Thus, the center 606 may serve as a turning point where the first helical resistor 608 ends and the second helical resistor 610 starts.

The first helical resistor 614 of the top resistor 604 ends at the center 612, and the second helical resistor 616 starts from the center 612. Thus, the center 612 may serve as a turning point where the first helical resistor 614 ends and the second helical resistor 616 starts.

The bottom and top resistors 602 and 604 may be formed of the same material or different materials. The first and second helical resistors 608 and 610 of the bottom resistor 602 may be formed of the same material or different materials. When the first and second helical resistors 608 and 610 are formed of the same material, the bottom resistor 602 has the same shape as the resistor 100 according to an embodiment of the present invention, and thus does not require a contact for electrically connecting the two resistors 608 and 610. However, when the first and second helical resistors 608 and 610 are formed of different materials, the bottom resistor 602 has the same shape as the resistor 200 according to a variation of an embodiment of the present invention, and thus additionally requires a contact for electrically connecting the two resistors 608 and 610.

Furthermore, the first and second helical resistors 614 and 616 of the top resistor 604 may be formed of the same material or different materials. When the first and second helical resistors 614 and 616 are formed of the same material, the top resistor 604 has the same shape as the resistor 100 according to an embodiment of the present invention, and thus does not require a contact for electrically connecting the two resistors 614 and 616. However, when the first and second helical resistors 614 and 616 are formed of different materials, the top resistor 604 has the same shape as the resistor 200 according a variation of an embodiment of the present invention, and thus additionally requires a contact for electrically connecting the two resistors 614 and 616.

In the above-described resistor 500 according to another embodiment of the present invention, the in-terminals of the bottom and top resistors 502 and 504 are formed in the same direction, and the out-terminals of the bottom and top resistors 502 and 504 are formed in the same direction. In the resistor 600 according to a variation of another embodiment of the present invention, however, the in-terminals of the bottom and top resistors 602 and 604 are formed in different directions, and the out-terminals of the bottom and top resistors 602 and 604 are formed in different directions. Therefore, the positions of the in-terminals and the out-terminals may be selected more freely than in the resistor 500 according to another embodiment of the present invention.

When the resistor 600 is formed in such a double-helical structure as in another variation of another embodiment of the present invention, the position of the out-terminal as well as the in-terminal may be freely selected. As a difference in distance between the logic circuit and the in- and out-terminals is minimized, it is possible to minimize the effect of an R/C value of the interconnection line of the out-terminal in addition to a specific resistance value. As the distance between the logic circuit and the out-terminal is increased, the R/C value of the interconnection line of the out-terminal is inevitably added to the entire resistance value. In the above-described resistor 600 having a double-helical structure, however, the position of the out-terminal may be freely adjusted to minimize the distance between the out-terminal and the logic circuit. Thus, the effect of the R/C value of the interconnection line may be minimized to thereby improve the reliability of the semiconductor memory device.

As described above, the resistor 600 according to an embodiment of the present invention includes the bottom and top resistors 602 and 604, for example, in a stacked structure. However, the resistor 600 may comprise any number of resistor layers. Therefore, as the number of resistor layers to be stacked in the same shape on the same vertical line is adjusted, a plurality of independent resistors each having an in-terminal and an out-terminal may be freely formed without additional area occupation.

Dummy patterns may be formed at the bottom and top resistors 602 and 604, respectively. In this case, the bottom and top resistors 602 and 604 may be more positively protected from an external stress by the dummy patterns.

According to the embodiments of the present invention, the resistor for driving/controlling memory cells formed in the cell area is formed in a helical structure to minimize a difference in distance between the logic circuit and the in- and out-terminals. As a result, the effect of the R/C value of the interconnection line in addition to a specific resistance value may be excluded as much as possible. Therefore, it is possible to further improve the reliability of the semiconductor memory device and increase the yield.

While certain embodiments have been described above, it will be understood to those skilled in the art that the embodiments described are by way of example only. Accordingly, the method described herein should not be limited based on the described embodiments. Rather, the method described herein should only be limited in light of the claims that follow when taken in conjunction with the above description and accompanying drawings.

What is claimed is:

1. A method of forming a resistor of a semiconductor memory device, comprising the steps of:
forming a first helical resistor extending from a first point toward a center in a clockwise or counterclockwise direction;
forming a second helical resistor extending from the center to a second point in a direction opposite of the first helical resistor;
wherein the first and second helical resistor are connected to each other at the center; and
wherein the first and second helical resistors do not overlap.

2. The method of claim 1, wherein the first helical resistor and second helical resistors exist in the same planar dimension.

3. The method of claim 2, wherein the first and second helical resistors are comprised of a same material.

4. The method of claim 2, wherein the first and second helical resistors are comprised of different materials.

5. The method of claim 4, further comprising the step of forming a contact at the center connecting the first and second helical resistors.

6. The method of claim 2, further comprising the step of forming a dummy pattern between the first and second helical resistors.

7. The method of claim 1, wherein the first helical resistor is formed on a first plane and the second helical resistor is formed on a second plane.

8. The method of claim 7, further comprising the step of forming a contact at a center of the first plane to a center of the second plane connecting the first and second helical resistors.

9. The method of claim 7, wherein the first and second resistors are comprised of a same material.

10. The method of claim 7, wherein the first and second helical resistors are comprised of different materials.

11. The method of claim 7, further comprising the step of forming a contact at the center connecting the first and second helical resistors.

12. A resistor structure of a semiconductor memory device, comprising:
a first helical resistor extending from a first point toward a center in a clockwise or counterclockwise direction;
a second helical resistor extending from the center to a second point in a direction opposite of the first helical resistor,
wherein the first and second helical resistors are connected to each other at the center, and
wherein the first and second helical resistors do not overlap.

13. The resistor structure of claim 12, wherein the first helical resistor and second helical resistor path exist in the same planar to dimension.

14. The resistor structure of claim 13, wherein the first and second helical resistors are comprised of a same material.

15. The resistor structure of claim 13, wherein the first and second helical resistors are comprised of different materials.

16. The resistor structure of claim 15, further comprising a contact at the center connecting the first and second helical resistors.

17. The resistor structure of claim 13, further comprising a dummy pattern between the first and second helical paths.

18. The resistor structure of claim 12, wherein the first helical resistor is formed on a first plane and the second helical resistor is formed on a second plane.

19. The resistor structure of claim 18, further comprising a contact at a center of the first plane to a center of the second plane connecting the first and second helical resistors.

20. The resistor structure of claim 19, wherein the first and second helical resistors are comprised of a same material.

21. The resistor structure of claim 19, wherein the first and second helical resistors are comprised of different materials.

22. The resistor structure of claim 18, further comprising a contact connected to the first and second helical resistors.
